(19) United States
(12) Patent Application Publication
(10) Pub. No.: US 2009/0166660 A1
(43) Pub. Date: Jul. 2, 2009

(54) Lead frame for LED

(76) Inventors: Roger Lee, Chung-Ho City (TW); Max Yu, Chung-Ho City (TW)

Correspondence Address: TROXELL LAW OFFICE PLLC;ONE SKYLINE PLACE, SUITE 1404, 5205 LEESBURG PIKE, FALLS CHURCH, VA, 22041, US

(21) Appl. No.: 12/010,097

(22) Filed: Jan. 18, 2008

(30) Foreign Application Priority Data
Oct. 5, 2007 (TW) 096137398

(51) Int. Cl. H01L 33/00; H01L 23/52; H01R 9/03

(52) U.S. Cl. 257/99; 257/666; 257/E33.066; 361/772; 257/E23.141

(57) ABSTRACT

A lead frame for LED is disclosed to include a body defining an accommodation chamber, a first bracket frame that has a first bottom base mounted in the accommodation chamber and a first connection leg and a second connection respectively extended from the first bottom base to the outside of the body and bent into shape, and a second bracket frame that has a second bottom base mounted in the accommodation chamber and a third connection leg and a fourth connection leg respectively extended from the second bottom base to the outside of the body and bent into shape.

### BACKGROUND OF THE INVENTION

1. Field of the Invention

The present invention relates to LED technology and more specifically, to a lead frame for LED that provides a broad heat dissipation area to reduce thermal resistance and to lower the junction temperature, enhancing the reliability of the LED and prolonging its lifetime.

2. Description of the Related Art

A side emitting type LED (light emitting diode) generally has a positive convection leg (Anode) and a negative connection leg (Cathode) for coupling to a circuit board while providing a passage for dissipation of heat to lower the temperature of the LED. FIG. 1 illustrates a side emitting type LED 100 made according to Nichia Corporation, Japan's USD490,062. As illustrated, the side emitting type LED 100 comprises a positive connection leg 120 and a negative connection leg 110 or coupling to a circuit board (not shown) and for dissipation of heat during operation of the LED chip 130.

According to the aforesaid prior art design, the connection legs 110 and 120 are respectively bent outwards from the two opposite short sides (or long sides) of the body, and the LED chip 130 in the body can only dissipate heat through the connection legs 110 or 120. This heat dissipation path is insufficient. When this design is used in a narrow space in a notebook computer or mobile electronic device, the high temperature of the LED will cause increasing of the temperature of the notebook computer or mobile electronic device, deteriorating the brightness of the notebook computer or mobile electronic device, or even causing burnout failure.

Therefore, it is desirable to design a lead frame for LED that eliminates the aforesaid problem.

### SUMMARY OF THE INVENTION

The present invention has been accomplished under the circumstances in view. It is therefore the main object of the present invention to provide a lead frame for LED, which has two connection legs respectively extending from one long side and one short side of each of two bracket frames thereof and then bent into shape to provide a broad heat dissipation area for quick dissipation of heat during operation of the LED.

It is another object of the present invention to provide a lead frame for LED, which effectively lowers the temperature of the LED, improving the working stability and reliability of the LED.

To achieve these and other objects of the present invention, the lead frame comprises a body, a first bracket frame, and a second bracket frame. The body has an accommodation chamber. The first bracket frame is located at the bottom side of the accommodation chamber, comprising a first flat base, a first connection leg and a second connection leg respectively extended from said first flat base. The first connection leg and the second connection leg are respectively extended out of one side of the body. The second bracket frame is located at the bottom side of the accommodation chamber at one side opposing to the first bracket frame, comprising a second flat base, a third connection leg and a fourth connection leg respectively extended from said second flat base. The third connection leg and the third connection leg are respectively extended out of an opposite side of the body.

### BRIEF DESCRIPTION OF THE DRAWINGS

FIG. 1 is a schematic drawing showing a LED assembly made according to USD490,062 issued to Nichia Corporation.

FIG. 2(a) is a schematic drawing showing an extended status of a lead frame for LED in accordance with a first embodiment of the present invention (the body excluded).

FIG. 2(b) is a schematic plain view of the lead frame for LED in accordance with the first embodiment of the present invention.

FIG. 2(c) is an elevational assembly view of the lead frame for LED in accordance with the first embodiment of the present invention.

FIG. 3 is a schematic drawing showing an extended status of a lead frame for LED in accordance with a second embodiment of the present invention (the body excluded).

FIG. 4(a) is a schematic drawing showing an extended status of a lead frame for LED in accordance with a third embodiment of the present invention (the body excluded).

FIG. 4(b) is a schematic plain view of the lead frame for LED in accordance with the third embodiment of the present invention.

FIG. 4(c) is an elevational assembly view of the lead frame for LED in accordance with the third embodiment of the present invention.

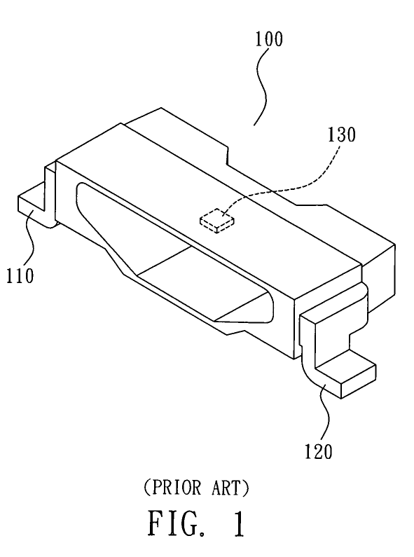

### DETAILED DESCRIPTION OF THE PREFERRED EMBODIMENT

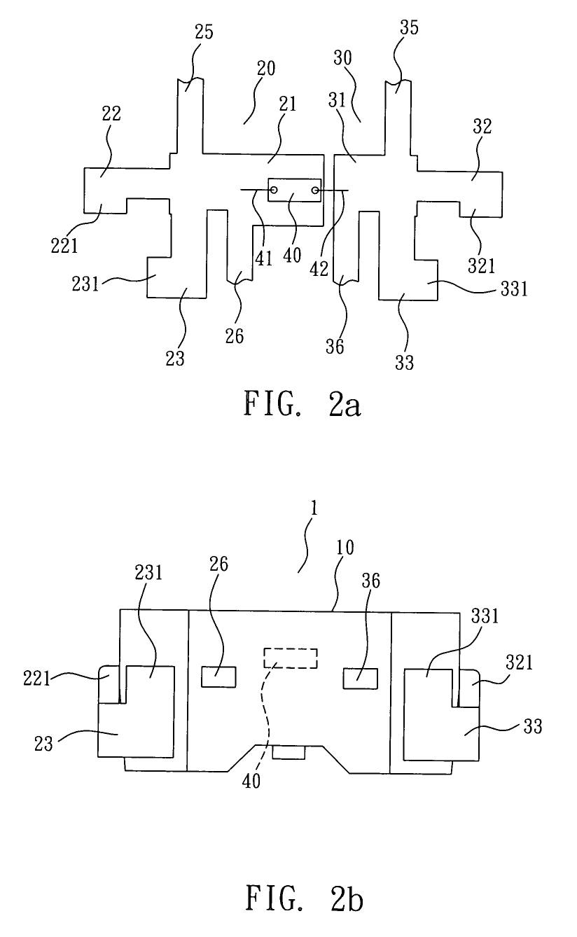

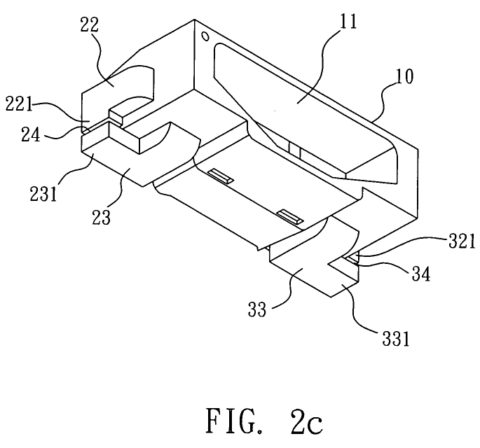

FIGS. 2(a) through 2(c) illustrate a lead frame for LED in accordance with a first embodiment of the present invention, in which FIG. 2(a) is a schematic drawing showing an extended status of a lead frame for LED in accordance with a first embodiment of the present invention (the body excluded); FIG. 2(b) is a schematic plain view of the lead frame for LED in accordance with the first embodiment of the present invention; FIG. 2(c) is an elevational assembly view of the lead frame for LED in accordance with the first embodiment of the present invention. As illustrated, the lead frame in accordance with the first embodiment of the present invention is used in a side emitting type LED (light emitting diode) 1. The lead frame comprises a body 10 defining an accommodation chamber 11, a first bracket frame 20, and a second bracket frame 30.

The body 10 is adapted for carrying the first bracket frame 20 and the second bracket frame 30. Further, the body 10 can be made out of but not limited to an electrically insulative material, for example, plastics.

The first bracket frame 20 is provided at the bottom side of the accommodation chamber 11, comprising a first bottom base 21, a first connection leg 22, and a second connection leg 23. The first bottom base 21 is adapted for holding a LED (light emitting diode) chip 40. The first connection leg 22 and the second connection leg 23 are respectively extended out of the body 10 and then bent into shape (see FIGS. 2(b) and 2(c)). The first connection leg 22 and the second connection leg 23 according to this embodiment are positive pole connection legs However, this arrangement is not a limitation. The first connection leg 22 extends from the left side of the first bottom base 21 and terminates in a first wing 221. The second connection leg 23 extends from the bottom side of the first bottom base 21 and terminates in a second wing 231. The second wing 231 extends leftwards from the free end of the second connection leg 23.

The first wing 221 and the second wing 231 extend in a perpendicular manner relative to each other. Further, the first wing 221 and the second wing 231 each have a transverse cut 24. The second connection leg 23 and the second wing 231 are for bonding to a circuit board (not shown), and the transverse cut 24 receives the applied solder paste to enhance the bonding strength and tightness.

The second bracket frame 30 is provided at the bottom side of the accommodation chamber 11 opposing the first bracket frame 20, comprising a second bottom base 31, a third connection leg 32, and a fourth connection leg 33. The first bottom base 21 is adapted for holding a LED (light emitting diode) chip 40. The third connection leg 32 and the fourth connection leg 33 are respectively extended out of the body 10 and then bent into shape (see FIGS. 2(b) and 2(c)). The third connection leg 32 and the fourth connection leg 33 according to this embodiment are negative pole connection legs. However, this arrangement is not a limitation. The third connection leg 32 extends from the right side of the second bottom base 31 and terminates in a third wing 331. The third wing 331 extends downwards from the free end of the third connection leg 32. The fourth connection leg 33 extends from the bottom side of the second bottom base 31 and terminates in a fourth wing 331 that extends rightwards from the free end of the fourth connection leg 33.

The third wing 321 and the fourth wing 331 extend in a perpendicular manner relative to each other. Further, the third wing 321 and the fourth wing 331 each have a transverse cut 34. The fourth connection leg 33 and the fourth wing 331 are for bonding to the same circuit board (not shown), and the transverse cut 34 receives the applied solder paste to enhance the bonding strength and tightness.

The first bottom base 21 has a first material strip 25 and a second material strip 26 respectively extended from its top and bottom sides. The first material strip 25 extends from the top side of the first bottom base 21 in direction reversed to the extending direction of the second connection leg 23. The second material strip 26 extends downwards from the bottom side of the first bottom base 21 and disposed in a parallel manner relative to the second connection leg 23 at the right side The second bottom base 31 has a third material strip 35 and a fourth material strip 36 respectively extended from its top and bottom sides. The third material strip 35 extends from the top side of the second bottom base 31 in direction reversed to the extending direction of the fourth connection leg 33. The fourth material strip 36 extends downwards from the bottom side of the second bottom base 31 and disposed in a parallel manner relative to the fourth connection leg 33 at the left side.

During assembly, the first material strip 25, the second material strip 26, the third material strip 35 and the fourth material strip 36 are respectively pre-cut, and then the first bracket frame 20 and the second bracket frame 30 are put in the mold (not shown), and the prepared molten plastic material is filled into the mold and molded into shape, forming the desired body 10 that covers the precut notches of the first material strip 25, the second material strip 26, the third material strip 35 and the fourth material strip 36. At this time, the body 10 is still kept connected with the first material strip 25, the second material strip 26, the third material strip 35 and the fourth material strip 36. Thereafter, the first connection leg 22 and the related first wing 221, the second connection leg 23 and the related second wing 231, the third connection leg 32 and the related third wing 321 and the fourth connection leg 33 and the related fourth wing 331 and cut into the respective predetermined contours by a cutting die (not shown) and then respectively bent into shape. Thereafter, a tool (not shown) is operated to disconnect the body 10 from the precut notches (not shown) of the first material strip 25, the second material strip 26, the third material strip 35 and the fourth material strip 36, and the desired lead frame for LED is thus obtained.

When installing a LED chip 40 having the positive pole and negative pole at the same side in the lead frame, the LED chip 40 is mounted to the first bottom base 21 of the first bracket frame 20, and then the negative pole (not shown) of the LED chip 40 is electrically connected to the first flat base 21 with a lead wire 41 to have the negative pole of the LED chip 40 be in electric connection with the first connection leg 22 (or second connection leg 23), and then the positive pole (not shown) of the LED chip 40 is electrically connected to the second bottom base 31 of the second bracket frame 30 with a lead wire 42 to have the positive pole of the LED chip 40 be in electric connection with the third connection leg 32 (or fourth connection leg 33), and then a molten adhesive is filled in the accommodation chamber 11 and hardened to protect the LED chips 40 and the lead wires 41 and 42. When an electric current is applied to the LED chip 40, a major part of the heat energy thus produced is transferred from the LED chip 40 through the first connection leg 22 and the second connection leg 23 to the first wing 221 and the second wing 231, and a minor part of the heat energy is transferred from the LED chip 40 through the third connection leg 32 and the fourth connection leg 33 to the third wing 321 and the fourth wing 331. The heat energy that is transferred to the second connection leg 23, the second wing 231, the fourth connection leg 33 and the fourth wing 331 is further transferred to the circuit board for quick dissipation. Further, the heat energy that is transferred to the first connection leg 22, the first wing 221, the third connection leg 32 and the third wing 321 is dissipated directly into the outside open air. Therefore, heat energy is quickly carried away from the LED chip 40 during operation.

If the LED chip 40 is a vertical connection type, the bottom positive electrode or negative electrode (not shown) of the LED chip 40 is directly mounted to the first bottom base 21, and the front negative electrode or positive electrode (not shown) is connected to the second bottom base 31 with a lead wire (not shown) in electric connection with the third connection leg 32 (or fourth connection leg 33). According to test, the use of the lead frame of the present invention in a notebook computer can lower the junction temperature of the LED subject to Tⱼₐ=Rₜₕ×W, in which Tⱼₐ is the junction temperature of the LED chip, Rₜₕ is the equivalent thermal resistance, and W is the total power ([Tⱼ=Tₐ+Rₜₕ×W] in which Tⱼ is the junction temperature of the LED chip, Tₐ is the ambient temperature, Rₜₕ is the thermal resistance, and W is the input power). Therefore, the lead frame of the present invention effectively eliminates the drawback of the prior art lead frame.

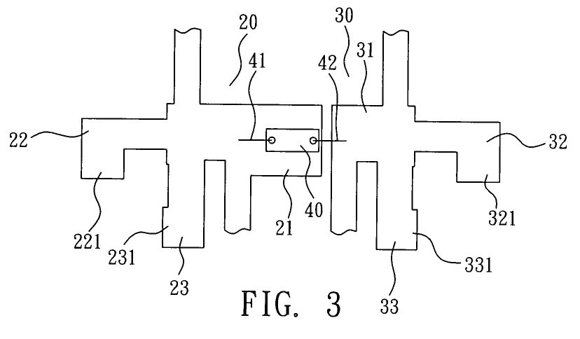

FIG. 3 is a schematic drawing showing an extended status of a lead frame for LED in accordance with a second embodiment of the present invention (the body excluded). This second embodiment is substantially similar to the aforesaid first embodiment with the exception that the first wing 221 and the second wing 231 are reversed in shape; the third wing 321 and the fourth wing 331 are reversed in shape.

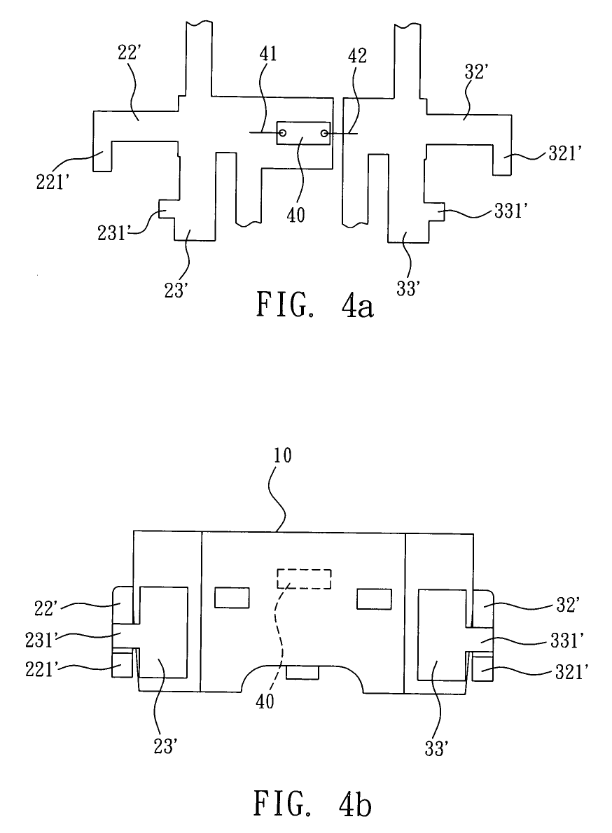

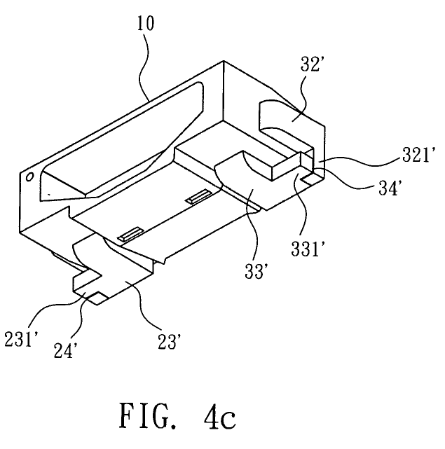

FIGS. 4(a) through 4(c) illustrate a lead frame for LED in accordance with a third embodiment of the present invention, in which FIG. 4(a) is a schematic drawing showing an extended status of a lead frame for LED in accordance with a third embodiment of the present invention (the body excluded); FIG. 4(b) is a schematic plain view of the lead frame for LED in accordance with the third embodiment of the present invention; FIG. 4(c) is an elevational assembly view of the lead frame for LED in accordance with the third embodiment of the present invention.

When compared to FIG. 2(a) of the aforesaid first embodiment, the first wing 221′ of the first connection leg 22′ of this third embodiment is relatively narrower and longer than that of the aforesaid first embodiment; the second wing 231′ of the second connection leg 23′ perpendicularly extends from the left side of the second connection leg 23′ near its free end (the second wing 231 shown in FIG. 2(a) extends leftwards from the free end of the second connection leg 23); the third wing 321′ of the third connection leg 32′ is relatively narrower and longer than that of the aforesaid first embodiment; the fourth wing 331′ of the fourth connection leg 33′ perpendicularly extends from right side of the fourth connection leg 33′ near its free end; the extending direction of the first wing 221′ is perpendicular to the extending direction of the second wing 231′; after having been bent into shape, the first wing 221′ and the second wing 231′ each have a longitudinal cut 24′, the third wing 321′ and the fourth wing 331′ each have a longitudinal cut 34′, and the wings 221′, 231′, 321′ and 331′ are arranged in a staggered manner. The staggered arrangement of the wings 221′, 231′, 321′ and 331′ facilitates upward climbing of solder paste through the longitudinal cuts 24′ and 34′, achieving the same effect as that shown in FIG. 2.

As stated, the first bracket frame and second bracket frame of the lead frame according to the present invention each have two connection legs respectively extended from one short side and one long side and then bent into shape, increasing the number of heat dissipation paths and the total heat dissipation area for quick dissipation of heat energy from the LED chip, and therefore the application of the present invention greatly improves the working stability and reliability of the LED, eliminating the drawback of the prior art design.

Although particular embodiments of the invention have been described in detail for purposes of illustration, various modifications and enhancements may be made without departing from the spirit and scope of the invention.

What is claimed is:

1. A lead frame comprising:
a body, said body having an accommodation chamber;
a first bracket frame located at a bottom side of said accommodation chamber, said first bracket frame comprising a first bottom base, a first connection leg and a second connection leg respectively extended from said first bottom base, said first connection leg and said second connection leg respectively extending out of one side of said body; and
a second bracket frame located at a bottom side of said accommodation chamber at one side opposing to said first bracket frame, said second bracket frame comprising a second bottom base, a third connection leg and a fourth connection leg respectively extended from said second bottom base, said third connection leg and said third connection leg respectively extending out of an opposite side of said body.

2. The lead frame as claimed in claim 1, wherein said first connection leg extends outwards from a left side of said first bottom base, said first connection leg having a first wing perpendicularly downwardly extending from a free end thereof; said second connection leg extends downwards from a bottom side of said first bottom base, said second connection leg having a second wing at a left side thereof.

3. The lead frame as claimed in claim 2, wherein said second wing extends perpendicularly from the left side of said second connection leg near a free end of said second connection leg.

4. The lead frame as claimed in claim 3, wherein said first wing and said second wing extend in a perpendicular manner relative to each other, each having a transverse cut; said second connection leg and said second wing are bonded to a circuit board.

5. The lead frame as claimed in claim 1, wherein said first connection leg and said second connection leg are positive pole connection legs.

6. The lead frame as claimed in claim 1, wherein said third connection leg extends outwards from a right side of said second bottom base, said second connection leg having a third wing downwardly extended from a free end thereof; said fourth connection leg extends downwards from a bottom side of said second bottom base, said fourth connection leg having a fourth wing at a right side thereof.

7. The lead frame as claimed in claim 6, wherein said third wing and said fourth wing extend in a perpendicular manner relative to each other, each having a transverse cut; said fourth connection leg and said fourth wing are bonded to the circuit board to which said second connection leg and said second wing are bonded.

8. The lead frame as claimed in claim 1, wherein said third connection leg and said fourth connection leg are negative pole connection legs.

9. The lead frame as claimed in claim 1, wherein said first bottom base has a first material strip and a second material strip respectively extending from top and bottom sides thereof, said first material strip extending from said first bottom base in direction reversed to said second connection leg, said second material strip extending from said first bottom base in a parallel manner relative to said second connection leg and spaced from said second connection leg at a right side.

10. The bottom as claimed in claim 1, wherein said second bottom base has a third material strip and a fourth material strip respectively extending from top and bottom sides thereof, said third material strip extending from said first bottom base in direction reversed to said fourth connection leg, said fourth material strip extending from said second bottom base in a parallel manner relative to said fourth connection leg and spaced from said second connection leg at a left side.

11. The lead frame as claimed in claim 2, wherein said second wing extends from a left side of said second connection leg near a free end of said second connection leg.

12. The lead frame as claimed in claim 11, wherein said first wing and said second wing extend in a perpendicular manner relative to each other, each having a longitudinal cut; said second leg and said second wing are bonded to a circuit board; said first wing and said second wing are arranged in a staggered manner after bonding of said second wing to said circuit board.

13. The lead frame as claimed in claim 6, wherein said fourth wing extends outwards from a right side of said fourth connection leg near a free end of said fourth connection leg.

14. The lead frame as claimed in claim 13, wherein said third wing and said fourth wing extend in a perpendicular manner relative to each other, each having a longitudinal cut; said fourth leg and said fourth wing are bonded to a circuit board; said third wing and said fourth wing are arranged in a staggered manner after bonding of said fourth wing to said circuit board.

15. The lead frame as claimed in claim 1, wherein said first bottom base of said first bracket frame has mounted thereon a light emitting diode chip.
